(19) United States
(12) Patent Application Publication
(10) Pub. No.: US 2001/0054904 A1
(43) Pub. Date: Dec. 27, 2001

(54) Monitoring resistor element and measuring method of relative preciseness of resistor elements

(76) Inventor: Itaru Inoue, Yamagata (JP)

Correspondence Address: ROSENMAN & COLIN LLP, 575 MADISON AVENUE, NEW YORK, NY, 10022-2585, US

(21) Appl. No.: 09/870,220

(22) Filed: May 30, 2001

(30) Foreign Application Priority Data
Jun. 2, 2000 (JP) 2000-166218

(51) Int. Cl. G01R 31/26

(52) U.S. Cl. 324/719

(57) ABSTRACT

A monitoring resistor element includes a plurality of resistors (1, 2) formed on an integrated circuit chip through the same fabrication steps as those used to form a practical circuit are connected to power source pads (3, 4, 5, 6), which are terminal pads formed on the integrated circuit chip. A method for measuring a relative preciseness of resistors (1, 2) formed on an integrated circuit chip includes the step of performing the relative preciseness of the resistors by using power source pads (3, 4, 5, 6), to which the resistors (1, 2) are connected and which are terminal pads formed on the integrated circuit chip, as measuring pads when the measurement of relative preciseness of the resistors (1, 2) is performed.

### BACKGROUND OF THE INVENTION

1. Field of the Invention

The present invention relates to a monitoring resistor element for monitoring a semiconductor integrated circuit and a measuring method of relative preciseness of resistors of semiconductor integrated circuit element.

2. Description of the Prior Art

In the measurement of relative preciseness of resistor elements, which substantially influences on the characteristics of a semiconductor integrated circuit, it is one of important factors to do the measurement accurately and efficiently.

In view of this fact, it is usual that a plurality of resistors are formed on each of semiconductor integrated circuit chips included in a semiconductor circuit wafer through the same fabrication steps as those used to form a practical circuit of the integrated circuit chip. Measuring pads also formed on the integrated circuit chip are connected to opposite ends of the respective resistor elements. The relative preciseness of the resistors is measured by measuring resistance values of the resistors by making probes of a testing device in direct contact with the respective measuring pads.

For example, Japanese Patent Laid-Open No. 5-157780 bulletin discloses a conventional monitoring resistor element and a measuring method of a relative preciseness of the resistors. As shown in FIG. 1, the conventional monitoring resistor element includes a first resistor 1 and a second resistor 2, which are formed on each of integrated circuit chips included in a semiconductor integrated circuit wafer through the same fabrication steps as those used in forming a practical circuit of the integrated circuit chip. A first measuring pad 21 and a second measuring pad 22 are connected to one ends of the first and second resistors 1 and 2, respectively, and the other ends of the first and second resistors 1 and 2 are short-circuited to each other by a metal wiring 24, which is connected to a third measuring pad 23. The connection between the metal wiring 24 and the one ends of first and second resistors 1 and 2 are achieved by contacts 7 and 9 and the connection between the first and second measuring pads 21 and 22 and the one ends of the first and second resistors 1 and 2 are achieved through contacts 8 and 10, respectively.

Describing the measuring method of the relative preciseness of the monitoring resistor element constructed as mentioned above, probes of a measuring device is made in direct contact with the first measuring pad 21, the second measuring pad 22 and the third measuring pad 23. The relative preciseness between the first resistor 1 and the second resistor 2 is measured by applying a voltage between the first measuring pad 21 and the second measuring pad 22 and measuring a voltage at the third measuring pad 23.

Assuming the voltages of the first, second and third measuring pads 21, 22 and 23 are v1, v2 and v3, respectively, the relative preciseness between a resistance value r1 of the first resistor 1 and a resistance value r2 of the second resistor 2 is obtained by the following equation:

relative preciseness=r1/r2=(v2−v3)/(v3−v1)

In the conventional measuring resistor element and the conventional measuring method of relative preciseness of the resistors mentioned above, the first, second and third measuring pads 21, 22 and 23 are formed only for use in the measurement. Therefore, the measuring condition of the resistors is limited to the semiconductor integrated circuit wafer including a plurality of integrated circuit chips. After the integrated circuit chips are cut apart from the semiconductor integrated circuit wafer and processed to form the integrated circuit chip products, the measurement of relative preciseness of resistors of each integrated circuit chip product is impossible. This is because those measuring pads are molded within the package and disconnected from external leads.

Furthermore, since it is necessary to provide a plurality of measuring pads (the first, second and third measuring pads 21, 22 and 23 in this case) separately from terminal pads of each integrated circuit chip for power sources and signals, there is a problem that an area of each integrated circuit chip is increased.

### SUMMARY OF THE INVENTION

An object of the present invention is to provide a monitoring resistor element and a method of measuring relative preciseness of resistors, with which the relative preciseness of resistors can be measured precisely and efficiently even for a semiconductor integrated circuit wafer including a plurality of integrated circuit chips and for each integrated circuit chip as a product.

Another object of the present invention is to provide a monitoring resistor element and a method of measuring relative preciseness of resistors, with which an increase of the area of integrated circuit chip due to measurement of relative preciseness of resistors can be restricted and the cost of the integrated circuit chip can be reduced.

A monitoring resistor element according to the present invention, which includes a plurality of resistor elements formed on an integrated circuit chip through the fabrication steps as those used to form a practical circuit of the integrated circuit chip and measuring pads connected to terminal portions of the respective resistors, is featured by that the measuring pads are terminal pads formed on the integrated circuit chip.

The present monitoring resistor element is further featured by that the terminal pads are power source pads. Moreover, the present monitoring resistor element is preferably formed in a corner area of the integrated circuit chip.

The present invention is further featured by that dummy resistors are formed on both sides of the monitoring resistor element.

In a measuring method of relative preciseness of resistors formed on an integrated circuit chip, the present method is featured by measuring the relative preciseness of the resistors by using terminal pads formed on the integrated circuit chip and connected to the resistors as measuring pads.

The present method is further featured by measuring the relative preciseness of resistors by using the power source pads, which are the terminal pads, as the measuring pads.

Furthermore, the present method is featured by measuring the relative preciseness of resistors formed on each of integrated circuit chips included in a semiconductor integrated circuit wafer.

The present method is further featured by measuring the relative preciseness of resistors formed on an integrated circuit chip as a product.

According to the present invention, the monitoring resistor element formed on an integrated circuit chip is connected to the power source pad formed on the integrated circuit chip. When the relative preciseness measurement of the resistors formed on the integrated circuit chip is performed, the power source pads formed on the integrated circuit chip as the terminal pads are used as the measuring pads.

### BRIEF DESCRIPTION OF THE DRAWINGS

FIG. 1 is a plan view of a monitoring resistors according to a conventional technique;

FIG. 2 is a plan view of a monitoring resistors according to a first embodiment of the present invention;

FIG. 3 is a plan view of a monitoring resistors according to a second embodiment of the present invention;

FIG. 4 is a plan view of a monitoring resistors according to a third embodiment of the present invention;

FIG. 5 is a plan view of a monitoring resistors as a comparative example with the present invention; and

FIG. 6 is an equivalent circuit of the monitoring resistor element shown in FIG. 2, for explaining the relative preciseness measuring method of the monitoring resistor element, according to the present invention.

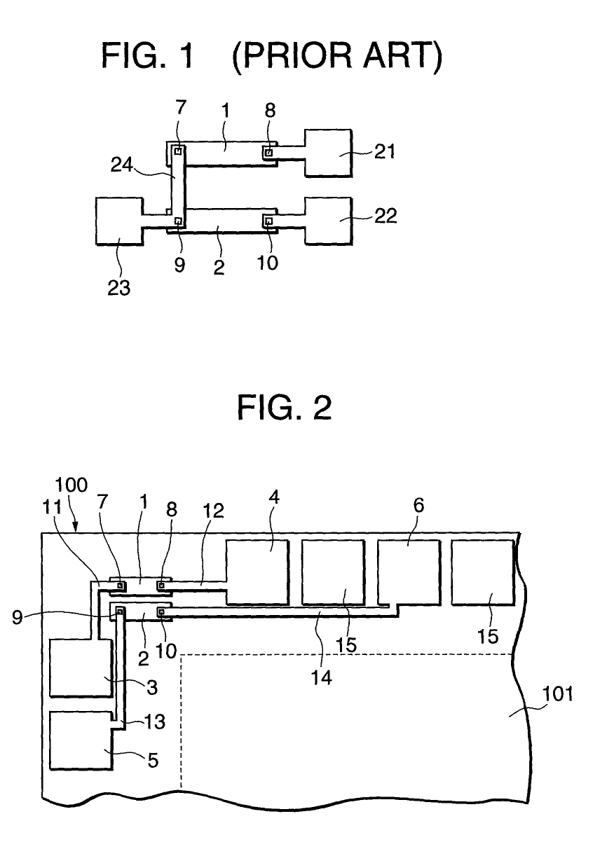

### DETAILED DESCRIPTION OF THE PREFERRED EMBODIMENTS

Referring to FIG. 2, power source pads (only a first power source pad 3, a second power source pad 4, a third power source pad 5 and a fourth power source pad 6 are shown in FIG. 2), which are terminal pads, and signal pads (only two signal pads 15 are shown in FIG. 2), which are also terminal pads, are formed on one of integrated circuit chips 100 included in a semiconductor integrated circuit wafer.

As shown in FIG. 2, a monitoring resistor element is formed in a corner region of the integrated circuit chip 100 through the same fabrication steps as those used to form a practical circuit region 101 defined by a dotted line. That is, the monitoring resistor element includes a first resistor 1 and a second resistor 2, which are formed through the same fabrication steps as those used to form the practical circuit. The monitoring resistor element further includes a metal wiring 11 connecting between one end of the first resistor 1 and the first power source pad 3 and a metal wiring 12 connecting between the other end of the first resistor element 1 and the second power source pad 4. The monitoring resistor element further includes a metal wiring 13 connecting between one end of the second resistor 2 and the third power source pad 5 and a metal wiring 14 connecting between the other end of the second resistor 2 and the fourth power source pad 6. The opposite ends of the first resistor 1 are connected to the metal wiring 11 and the metal wiring 12 through contacts 7 and 8, respectively. The opposite ends of the second resistor 2 are connected to the metal wiring 13 and the metal wiring 14 through contacts 9 and 10, respectively. These metal wirings and the respective pads are preferably formed simultaneously by using a metal material.

By using the monitoring resistor element constructed as mentioned above, measuring pads, which are dedicated to only the measurement of relative preciseness of the resistors in the conventional technique, becomes unnecessary, so that the increase of area of the integrated circuit chip, which is necessary in order to perform a relative preciseness measurement, is restricted and, hence, the cost of the integrated circuit chip can be reduced.

Although the configurations, the sizes and the arrangement of the first resistor 1 and the second resistor 2 are preferably the same as those of resistors, which are practically used in the practical circuit formed within the integrated circuit chip and whose relative preciseness is to be confirmed, they may not be limited thereto.

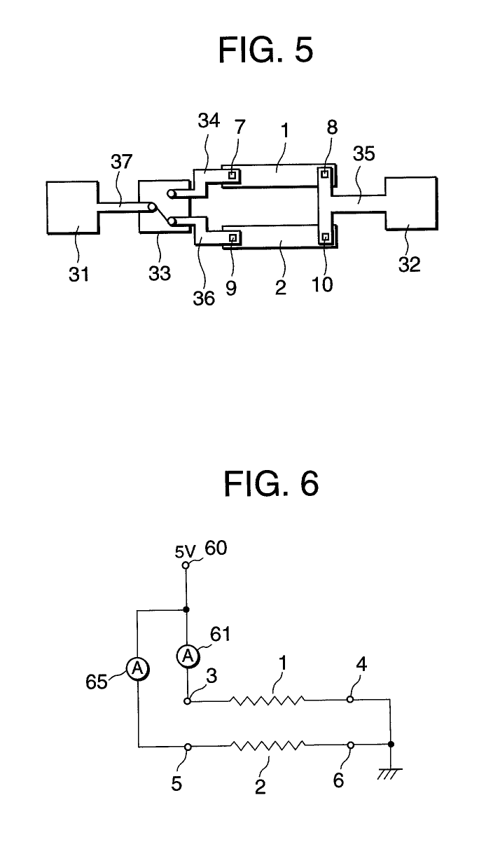

Incidentally, in order to reduce the number of the measuring pads, an arrangement shown in FIG. 5 may be considered. This arrangement includes a monitoring resistor element formed on each of integrated circuit chips included in a semiconductor integrated circuit wafer through the same fabrication steps as those used in a fabrication of a practical circuit of the integrated circuit chip. That is, it includes a first resistor 1 and a second resistor 2, which are formed on the integrated circuit chip of the semiconductor integrated circuit wafer through the same fabrication steps as those used in the fabrication of the practical circuit. Furthermore, the arrangement is provided, on the integrated circuit chip, with a switch circuit 33 formed through the same fabrication steps as those used in the fabrication of the practical circuit. Moreover, the arrangement includes a first measuring pad 31 and a second measuring pad 32 and one end of the first resistor 1 is connected to the switch circuit 33 by a metal wiring 34. One end of the second resistor 2 is connected to the switch circuit 33 by a metal wiring 36. A metal wiring 35 for short-circuiting between the other end of the second resistor 1 and the other end of the second resistor 2 is connected to the second measuring pad 32. The switch circuit 33 is connected to the first measuring pad 31 by a metal wiring 37. The one ends of the first and second resistors 1 and 2 and the metal wirings 34 and 36 are electrically connected through contacts 7 and 9. The other ends of the first and second resistors 1 and 2 and the metal wiring 35 are electrically connected through contacts 8 and 10.

In testing the integrated circuit chip of the semiconductor integrated circuit wafer, probes of a testing device are made in direct contact with the first and second measuring pads 31 and 32. Then, a voltage is applied between the first and second measuring pads 31 and 32 and the relative precision of the first and second resistors 1 and 2 is measured by measuring resistance values of the first and second resistors 1 and 2 while switching the switch circuit 33 according to an instruction from the testing device.

In this comparison example, however, the switch circuit 33 is usually constructed with a MOS transistor and the resistance values of the first and second resistors 1 and 2 are measured through the MOS transistor. Therefore, an ON resistance of the MOS transistor is also measured, so that there is a problem that the measuring accuracy of the resistors may be degraded.

Furthermore, since the switch circuit 33 and the first and second measuring pads 31 and 32, which are unnecessary for the original integrated circuit chip, are required, the area of the integrated circuit chip is increased.

In the present invention, however, there is no switch circuit required and, therefore, there is no case where the accuracy of measurement of the resistors is degraded. Moreover, according to the present invention, the monitoring resistor element provided between pads of each of the integrated circuit chips are left as they are after the relative preciseness measurement, so that the monitoring resistor element can be used as a protective circuit between power source pads.

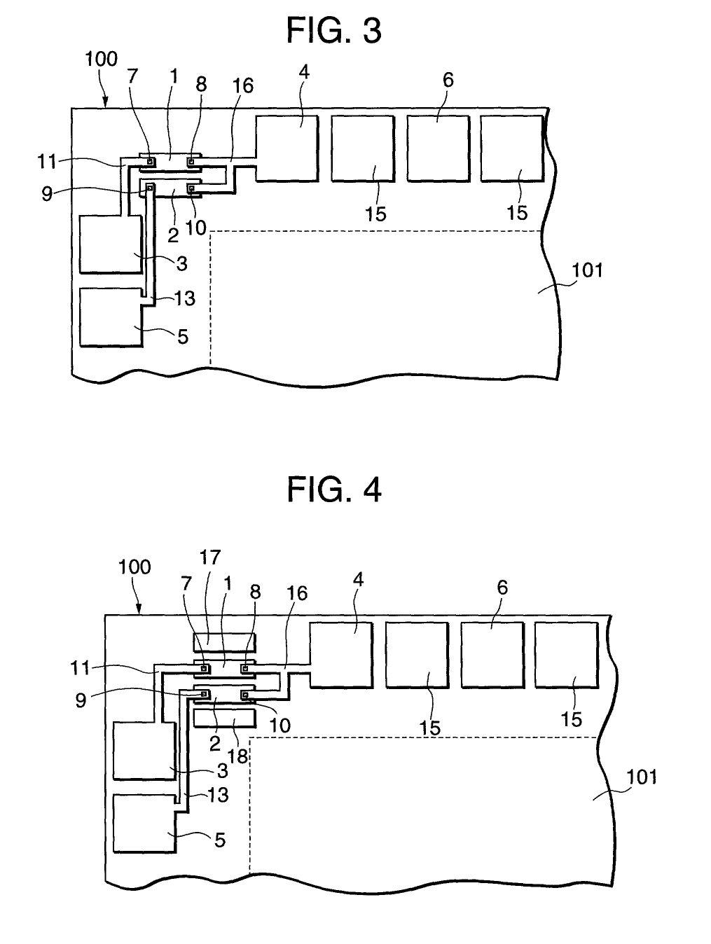

A monitoring resistor element according to a second embodiment of the present invention will be described with reference to FIG. 3. Contrary to the first embodiment shown in FIG. 2 in which the one ends of the first and second resistors 1 and 2 are connected to the first and third power source pads 3 and 5 through the metal wirings 11 and 13 and the other ends of the first and second resistors 1 and 2 are connected to the second and fourth power source pads 4 and 6 through the metal wirings 12 and 14, respectively, the monitoring resistor element of this embodiment includes the first and second resistors 1 and 2 having one ends connected commonly and connected to the second power source pad 4 through a metal wiring 16, as shown in FIG. 3.

Therefore, although the number of the power source pads in the first embodiment is twice the number of the resistors to be measured, that is, the number of terminals of the resistors, the number of power source pads in the second embodiment is only the number of resistors plus one since one ends of the resistors are connected commonly.

FIG. 4 is a plan view of a monitoring resistor element according to a third embodiment of the present invention. In order to improve the relative preciseness of resistors, there is a case where dummy resistors are arranged on both sides of a plurality of resistors according to a practical arrangement of resistors within an integrated circuit chip. The third embodiment of the present invention employs such dummy resistors. In the third embodiment, a dummy resistor 17 is arranged adjacent to a first resistor 1 and a dummy resistor 18 is arranged adjacent to a second resistor 2.

By adaptively arranging the resistors of the monitoring resistor element to a practical arrangement of resistors within an integrated circuit chip in this manner, it becomes possible to faithfully monitor the relative preciseness of the resistors used within the integrated circuit chip.

Furthermore, in the third embodiment of the monitoring resistor element described above, two resistors, that is, the first and second resistors 1 and 2, are formed on an integrated circuit chip 100. However, the number of resistors of the monitoring resistor element may be three or more according to a practical arrangement of resistors within the integrated circuit chip.

Moreover, in the third embodiment of the monitoring resistor element mentioned above, the integrated circuit chip on which the monitoring resistor element is formed is one of the integrated circuit chips included in the semiconductor integrated circuit wafer. However, the integrated circuit chip on which the monitoring resistor element is formed may be in the state of an individual product assembled by using a known technology.

As will be clear from the preferred embodiments shown in FIG. 2 to FIG. 4, since rows of the terminal pads for the power source and the signals are formed in a peripheral area of each integrated circuit chip except corner portions thereof, it is possible to form the monitoring resistor element in one of the corner portions in which there is no terminal pad formed. With this construction, there is no increase of area of the integrated circuit chip.

Now, a method of measuring the relative preciseness of resistors, according to the present invention will be described in detail with reference to FIG. 2, which shows the first embodiment of the monitoring resistor element.

First, as shown in FIG. 2, the first resistor 1 and the second resistor 2 are formed on one of the integrated circuit chips included in the semiconductor integrated circuit wafer, with the one ends of the first and second resistors 1 and 2 being connected to the first and third power source pads 3 and 5 through the metal wirings 11 and 13, respectively, and the other ends thereof being connected to the second and fourth power source pads 4 and 6 through the metal wirings 12 and 14, respectively.

The method of measuring the relative preciseness of resistors, according to a first embodiment, utilizes a testing device for testing the integrated circuit chip included in the semiconductor integrated circuit wafer. Probes of the testing device are made in direct contact with the first, second, third and fourth power source pads 3, 4, 5 and 6, respectively.

A voltage is applied between the first and second power source pads 3 and 4 and a current flowing through the first resistor 1 is measured. Similarly, a current flowing through the second resistor 2 is measured by applying a voltage between the third and fourth power source pads 5 and 6. A relative preciseness of the first and second resistors 1 and 2 is calculated on the basis of the voltage values applied between the power source pads and the measured values of currents flowing through the respective resistors.

In more detail, the voltage applied to the second power source pad 4 is fixed to 0V and the current flowing through the first resistor 1 is measured by applying a voltage to the first power source pad 3. Alternatively, it is possible in this case to fix the voltage applied to the first power source pad 3 to 0V and the current flowing through the second resistor 2 is measured by applying a voltage to the fourth power source pad 6.

Similarly to the measurement of the first resistor 1, the voltage applied to the fourth power source pad 6 is fixed to 0V and the current flowing through the second resistor 2 is measured by applying a voltage to the third power source pad 5. Alternatively, it is possible in this case to fix the voltage applied to the third power source pad 5 to 0V and the current flowing through the second resistor 2 is measured by applying a voltage to the fourth power source pad 6.

Representing the resistance values of the first and second resistors 1 and 2 by R1 and R2, respectively, the voltage values applied to the first power source pad 3 or the second power source 4 by VI, the current value flowing through the first resistor 1 by I1, the voltage value applied to the third power source pad 3 or the fourth power source pad 6 by V2 and the current value flowing through the second resistor 2 by I2, the relative preciseness of the first and second resistors 1 and 2 can be obtain by the following equation:

relative preciseness=R1/R2=(V1*I2)/(V2*I1)

As an example, a case where the relative preciseness of two resistors having resistance values R1 and R2, which are the same resistance values in design is measured with using the D.C. 5V as the output voltage of the power source 60 will be described with reference to FIG. 6, which is an equivalent circuit of the monitoring resistor element shown in FIG. 2. The D.C. voltage of 5V is applied to the first and second power source pads 3 and 5 and, when the second and fourth power source pads 4 and 6 are grounded, the current flowing through the resistors are measured by using a first ammeter 61 provided between the power source 60 and the first power source pad 3 and a second ammeter 61 provided between the power source 60 and the third power source pad 5. Assuming that the measured current values are I1=0.004 A and I2 0.005 A, the relative preciseness R1/R2 becomes as follow:

R1/R2=(5*0.005)/(5*0.004)=1.25

Therefore, the resistance value R1 of the first resistor 1 deviates by 25% relative to the resistance value R2 of the second resistor 2. In this example, R1=1250 Ω and R2=1000 Ω.

Incidentally, in measuring the relative preciseness of the first and second resistors 1 and 2, the voltage is applied to the first or second power source pad 3 or 4 and the third or fourth power source pad 5 or 6. However, since no clock signal is inputted to the practical circuit of the integrated circuit chip, the practical circuit connected to these power source pads does not operate and the measurement of the first and second resistors 1 and 2 is not influenced by the practical circuit.

A second embodiment of the measuring method of relative preciseness of resistors, according to the present invention, measures a first and second resistors 1 and 2 of an integrated circuit chip as a product by utilizing a testing device for testing the integrated circuit chip as the product, contrary to the first embodiment which measures the first and second resistors 1 and 2 of each of the integrated circuit chips included in the semiconductor integrated circuit wafer, by utilizing the testing device for testing the resistor elements of the integrated circuit chips included in the semiconductor integrated circuit wafer.

Each of the integrated circuit chips included in the semiconductor integrated circuit wafer, on which the monitoring resistor element is formed as shown in FIG. 2, becomes a product by assembling together with required elements according to any known technology. In the integrated circuit chip in the form of the product, the first, second, third and fourth power source pads 3, 4, 5 and 6 are connected to external leads (not shown) through bonding wires, for example.

In this embodiment, the testing device for testing the integrated circuit product is used and plugs provided in a test board of the testing device are made in contact with the external leads to which the first, second, third and fourth power source pads 3, 4, 5 and 6.

Then, current flowing through the first resistor 1 by applying a voltage between the first power source pad 3 and the second power source pad 4 and current flowing through the second resistor 2 by applying a voltage between the third power source pad 5 and the fourth power source pad 6 are measured, similarly to the first embodiment. A relative preciseness of the first and second resistors 1 and 2 is calculated on the basis of the voltage values applied between the power source pads and the measured current values flowing through the respective resistor elements.

As described hereinbefore, according to the present invention, the monitoring resistor element formed on the integrated circuit chip is connected to the power source pads formed on the same circuit chip and, when the relative preciseness of resistors is measured, the power source pads formed on the integrated circuit chip are used as the measuring pads. Therefore, it is possible to efficiently perform the measurement of the monitoring resistor element formed on the integrated circuit chip regardless of its state, the product state or the state included as one of the integrated circuit chips included in the semiconductor integrated circuit wafer, by using the testing device.

Furthermore, since the monitoring resistor element does not include a switch circuit such as shown in FIG. 5, the accuracy of the measurement of resistor element is not degraded, so that a highly accurate measurement becomes possible.

Moreover, since the monitoring resistor element according to the present invention does not require the measuring pads dedicated to the relative preciseness measurement, which are indispensable in the prior art, and the switch circuit such as shown in FIG. 5 is unnecessary, it is possible to restrict the increase of area of the integrated circuit chip, which may be caused by the relative preciseness measurement, to thereby reduce the cost of the integrated circuit chip.

Furthermore, according to the present invention, the monitoring resistor element provided between the pads of each integrated circuit chip can be left as it is after the relative preciseness measurement. In such case, the monitoring resistor element may be used as a protective circuit between the power source pads.

What is claimed is:

1. A monitoring resistor element comprising:
a plurality of resistors formed on an integrated circuit chip through the same fabrication steps as those used to form a practical circuit of said integrated circuit chip; and
measuring pads connected to ends of said respective resistors, said measuring pads being terminal pads formed on said integrated circuit chip.

2. A monitoring resistor element as claimed in claim 1, wherein said terminal pads are power source pads, respectively.

3. A monitoring resistor element as claimed in claim 1, wherein said monitoring resistor element is formed on a corner area of said integrated circuit chip.

4. A monitoring resistor element as claimed in claim 1, further comprising dummy resistors provided on both sides of said resistors.

5. A method of measuring a relative preciseness of resistors formed on an integrated circuit chip, comprising the steps of:
measuring values of said resistors by using terminal pads formed on said integrated circuit chip and connected to said resistor elements as measuring pads.

6. A method as claimed in claim 5, wherein said measuring pads are power source pads and values of D.C. currents flowing through said resistor elements by using said power source pads as said power source pads are measured.
